(19) United States
(12) Patent Application Publication
(10) Pub. No.: US 2020/0042126 A1
(43) Pub. Date: Feb. 6, 2020

(54) TOUCH DISPLAY PANEL AND DRIVING METHOD

(71) Applicant: Wuhan China Star Optoelectronics Semiconductor Display Technology Co.,Ltd., Wuhan Hubei (CN)

(72) Inventor: Xiaoliang FENG, Wuhan Hubei (CN)

(73) Assignee: Wuhan China Star Optoelectronics Semiconductor Display Technology Co., Ltd., Wuhan Hubei (CN)

(21) Appl. No.: 16/308,464

(22) PCT Filed: Sep. 7, 2018
(86) PCT No.: PCT/CN2018/104474

§ 371 Date: Dec. 9, 2018

(30) Foreign Application Priority Data
Aug. 1, 2018 (CN) 201810863721.3

(51) Int. Cl. G06F 3/041; H01L 27/32

(52) U.S. Cl. CPC G06F 3/0412; G06F 2203/04106; H01L 27/323; G06F 3/0416

(57) ABSTRACT

A touch display panel having a touch layer is provided. The touch layer includes N driving circuits, M receiving circuits, M×N sensing touch electrodes and N switches. M and N are integers greater than or equal to one. Each of the N driving circuits connected with two or more driving touch electrodes. Each of the N switches includes a controlling terminal, M input terminals connected to the M×N sensing touch electrodes correspondingly, and M output terminals connected to the M receiving circuits correspondingly. Each of the driving circuits is correspondingly provided with the M sensing touch electrodes arranged in columns connected to the same switch.

### BACKGROUND

### 1. Field of the Disclosure

The present disclosure relates to the touch technology, and more particularly, to a touch display panel and a method of driving the touch display panel.

### 2. Description of the Related Art

With the rapid development of the display technology, an organic light emitting diode (OLED) display device has the advantages of self-illumination, fast response, wide viewing angle, high brightness, and low power consumption. So an OLED display device can be widely applied to a cellphone, television, and a wearable electronic device. With the development of portable electronic display devices, the touch technology provides a new human-computer interaction interface, which integrates the touch technology and the display technology to form a touch display device and performs input through fingers or a stylus. In this way, the creation becomes easier and more intuitive.

At present, the more commonly used touch technologies are mainly divided into oncell touch technology and incell touch technology. Since the incell touch technology makes the display device thinner and lighter than the oncell touch technology, the incell touch technology, which is applied to an OLED display device better, should be paid more attention. The incell touch technology is divided into oncell touch technology and incell touch technology. During the manufacturing process of the touch layer of the oncell structure, processes such as evaporation and etching may cause damage to an OLED display device, thereby lowering the yield rate of the touch display panel.

In summary, the oncell touch technology of the related art may cause damage to an OLED device during the process of fabricating the touch layer, thereby affecting the yield rate of the touch display panel.

### SUMMARY

The present disclosure proposes a touch display panel to resolve the problems of a touch display panel of the related art. While a touch layer in the touch display panel is fabricated, the processes such as evaporation and etching may damage an organic light emitting diode (OLED) device, which further affects display.

According to a first aspect of the present disclosure, a touch display panel comprising a touch layer is provided. The touch layer includes N driving circuits, M receiving circuits, M×N sensing touch electrodes and N switches. M and N are integers greater than or equal to one. Each of the N driving circuits connected with two or more driving touch electrodes. Each of the sensing touch electrodes is independent from the adjacent sensing touch electrodes. Each of the N switches includes a controlling terminal, M input terminals connected to the M×N sensing touch electrodes correspondingly, and M output terminals connected to the M receiving circuits correspondingly. Each of the driving circuits is correspondingly provided with the M sensing touch electrodes arranged in columns connected to the same switch.

According to the present disclosure, the N driving circuits are arranged in columns; the M input terminals of each of the switches is connected to the M sensing touch electrodes corresponding to the driving circuits in each column; the M output terminals of each of the switches is connected to the M receiving circuits.

According to the present disclosure, the driving touch electrodes and the sensing touch electrodes are independent of each other.

According to the present disclosure, the touch layer further comprises a bridging line; the bridging line is connected to the two adjacent driving touch electrodes on each of the driving circuits.

According to the present disclosure, each of the sensing touch electrodes comprises two or more metallic electrodes. The adjacent metallic electrodes are connected through the bridging line.

According to a second aspect of the present disclosure, a method of driving a touch display panel includes driving an Nth driving circuit during a predetermined time period where N is an integer greater than or equal to one, turning an Nth switch on, receiving a sensing signal of M sensing touch electrodes corresponding to the Nth driving circuit where M is an integer greater than or equal to one.

According to the present disclosure, the touch display panel includes N driving circuits, M receiving circuits, M×N sensing touch electrodes and N switches. M and N are integers greater than or equal to one. Each of the N driving circuits connected with two or more driving touch electrodes. Each of the sensing touch electrodes is independent from the adjacent sensing touch electrodes. Each of the N switches includes a controlling terminal, M input terminals connected to the M×N sensing touch electrodes correspondingly, and M output terminals connected to the M receiving circuits correspondingly. Each of the driving circuits is correspondingly provided with the M sensing touch electrodes arranged in columns connected to the same switch.

According to the present disclosure, the N driving circuits are arranged in columns. The M input terminals of each of the switches is connected to the M sensing touch electrodes corresponding to the driving circuits in each column. The M output terminals of each of the switches is connected to the M receiving circuits.

According to the present disclosure, selectively turning on one of the N switches during the predetermined time period.

According to a third aspect of the present disclosure, a touch display panel comprising a touch layer is provided. The touch layer includes N driving circuits, M receiving circuits, M×N sensing touch electrodes and N switches. M and N are integers greater than or equal to one. Each of the N driving circuits connected with two or more driving touch electrodes. Each of the N switches includes a controlling terminal, M input terminals connected to the M×N sensing touch electrodes correspondingly, and M output terminals connected to the M receiving circuits correspondingly. Each of the driving circuits is correspondingly provided with the M sensing touch electrodes arranged in columns connected to the same switch.

According to the present disclosure, the N driving circuits are arranged in columns; the M input terminals of each of the switches is connected to the M sensing touch electrodes corresponding to the driving circuits in each column; the M output terminals of each of the switches is connected to the M receiving circuits.

According to the present disclosure, the driving touch electrodes and the sensing touch electrodes are independent of each other.

According to the present disclosure, the touch layer further comprises a bridging line; the bridging line is connected to the two adjacent driving touch electrodes on each of the driving circuits.

According to the present disclosure, each of the sensing touch electrodes comprises two or more metallic electrodes. The adjacent metallic electrodes are connected through the bridging line.

The present disclosure which especially provides a single-layer multi-touch layer brings beneficial effects of lessening the thickness of the OLED device, simplifying the manufacturing process, and reducing the risk of damage to the display layer.

### BRIEF DESCRIPTION OF THE DRAWINGS

The accompanying drawings described herein are used to provide further comprehension of the present disclosure, and is a part of the present application. Schematic embodiments of the present invention and the description thereof are used to illustrate the present disclosure, but do not constitute any improper limit to the present disclosure. In the accompanying drawings:

FIG. 1 illustrates a cross-sectional diagram of a touch display panel according to a first embodiment of the present disclosure.

FIG. 2 illustrates a schematic diagram of a touch layer of the touch display panel according to the first embodiment of the present disclosure.

FIG. 3 illustrates a top view of the touch layer of the touch display panel according to the first embodiment of the present disclosure.

FIG. 4 illustrates a timing diagram of signals applied on the touch display panel of the present disclosure.

### DETAILED DESCRIPTION OF THE EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The present disclosure is directed to a touch display panel of the related art. In the process of fabricating a touch layer, processes such as evaporation and etching, may cause damage to an organic light emitting diode (OLED) device, thereby affecting display or other technical problems. The problems can be well resolved according to the embodiment of the present disclosure.

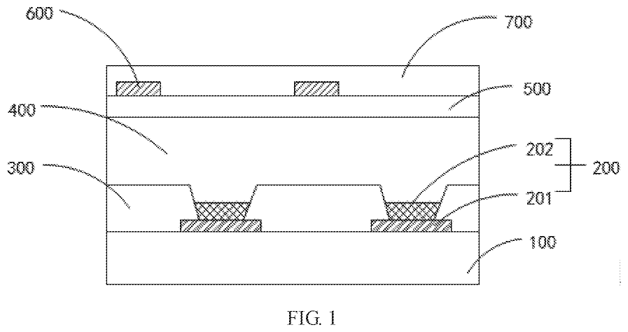

FIG. 1 illustrates a cross-sectional diagram of a touch display panel according to a first embodiment of the present disclosure. The touch display panel includes a substrate 100, an organic light emitting diode (OLED) device 200, a pixel defining layer 300, an encapsulating layer 400, an insulating layer 500, a touch layer 600, and a protective layer 700.

The touch layer 600 includes N driving circuits Tx, M receiving circuits Rx, N switchers SW, a plurality of driving touch electrodes 603, M multiplied by N sensing touch electrodes 604, and a plurality of bridging lines 602. The N is an integer greater than or equal to one. The M is an integer greater than or equal to one as well.

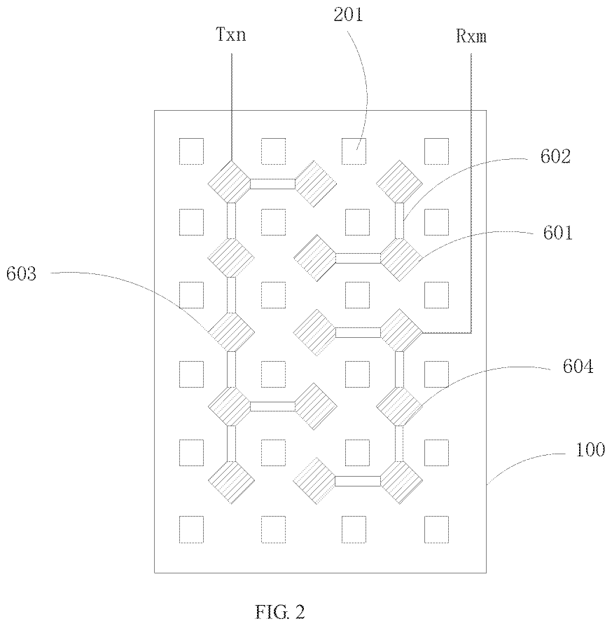

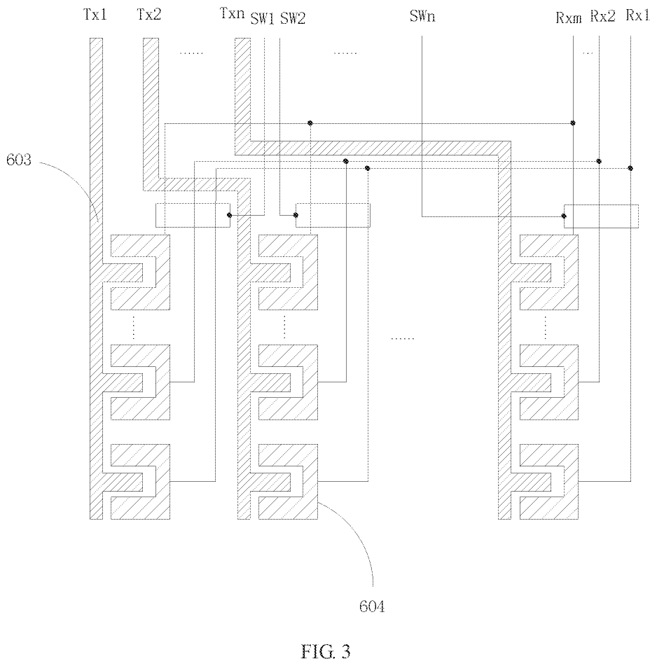

Please refer to FIG. 2 and FIG. 3. The N driving circuits Tx are Tx1 to Txn. The n is an integer greater than or equal to one. The N is equal to the n.

The M receiving circuits are Rx1 to Rxm. The m is an integer greater than or equal to one. The M is equal to the m.

The N switchers SW are SW1 to SWn.

The driving touch electrodes 603 and the sensing touch electrodes 604 are all formed by a metallic electrode 601 or the combination of a plurality of metallic electrodes 601. The metallic electrodes 601 are arranged in a matrix.

The metallic electrode 601 in this embodiment is a diamond-shaped grid pattern. The grid pattern is formed by staggering a plurality of metallic lines. The metallic electrode has lower resistance than indium tin oxide (ITO) electrode. Besides, the sensing electrode made of metal has the characteristics of high sensitivity and quick response, which reduces the manufacturing cost and the process difficulty. The metallic line is good for making a flexible display panel as well.

Each of the driving circuits Tx is connected to a plurality of driving touch electrodes 603. One of the driving touch electrodes 603 on each of the driving circuits Tx is connected to one of the neighboring driving touch electrode 603 on the same driving circuits Tx through one of the plurality of bridging lines 602.

The N driving circuits Tx are arranged in columns. The driving circuits Tx in each column is correspondingly provided with M sensing touch electrodes 604 arranged in columns.

Each of the switches SW includes a controlling terminal, M input terminals, and M output terminals.

The controlling terminal is configured to control disconnecting and turning-off states of the switch SW.

The M input terminals are connected to the M sensing touch electrodes 604 in each column, respectively. The M sensing electrodes 604 in each column are controlled by the same switch SW. Compared with the touch technology of the related art, the process flow introduced by the present disclosure is shortened and the risk of damage to the OLED device is reduced as well.

The M output terminals are connected to the M receiving circuits, respectively. Specifically, the M output terminals are connected to binding areas of the M receiving circuits, respectively.

For example, the M input terminals of the switch SW1 are connected to the M sensing touch electrodes 604 in a first column corresponding to the driving circuits Tx1, respectively. The M output terminals of the switch SW1 are connected to the M receiving circuits Rx1 to Rxm, respectively.

The N sensing touch electrodes 604 in each row is connected to the same receiving circuit Rx via the N switchers SW, respectively.

For example, the N sensing touch electrodes 604 in the first row are connected to Rxm after passing through the N switches SW1 to SWn.

One of the sensing touch electrodes 604 in this embodiment includes five metallic electrodes 601. The five metallic electrodes 601 are connected to one another through the bridging lines 602.

The sensing touch electrode 604 and its adjacent sensing touch electrode 604 are not connected to each other; in other words, the two adjacent sensing touch electrodes 604 both are independent.

The driving touch electrode 603 and the sensing touch electrode 604 are not connected to each other, that is, independent.

The touch layer 600 in this embodiment adopts a single-layer multi-touch method, which can reduce the complexity of the processes and the thickness of the OLED device.

The substrate 100 includes a substrate, a thin film transistor (TFT) layer, a source, a drain, and an insulating layer. The substrate may be a glass substrate or a flexible substrate.

The OLED device 200 is formed on the substrate 100. The OLED device 200 includes an anode 201, a hole injecting layer, a hole transport layer, a light emitting layer 202, an electron transport layer, an electron injecting layer, and a cathode. The anode 201, the hole injecting layer, the hole transport layer, the light emitting layer 202, the electron transport layer, the electron injecting layer, and the cathode are sequentially disposed on the substrate 100. The anode 100 is electrically connected to the source or the drain.

The pixel defining layer 300 is formed on the substrate 100. A contact hole is arranged on the pixel defining layer 300 and configured to accommodate a part of the OLED device 200 like the light emitting layer 202.

The encapsulating layer 400 is formed on the surface of the OLED device 200 and covers the OLED device 200. The encapsulating layer 400 includes a first inorganic encapsulating layer, an organic encapsulating layer, and a second inorganic encapsulating layer. The first inorganic encapsulating layer, the organic encapsulating layer, and the second inorganic encapsulating layer are disposed in sequence. The second inorganic encapsulating layer covers the organic encapsulating layer and the OLED device 200. The first inorganic encapsulating layer and the second inorganic encapsulating layer are both fabricated by silicon nitride material or silicon oxide material.

The insulating layer 500 is formed on the surface of the encapsulating layer 400 and configured to provide the touch layer 600 with a surface with more powerful attachment.

The touch layer 600 is formed on the surface of the insulating layer 500.

The 700 is formed on the surface of the touch layer 600 and configured to cover and protect the touch layer 600.

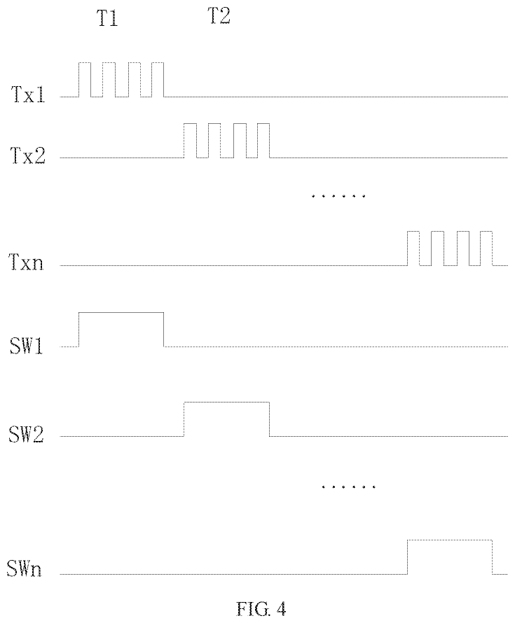

As illustrated in FIG. 4, in a specific time T1, the first driving circuit Tx1 is driven and the switch SW1 is turned on so as to receive sensing signals of the M sensing touch electrodes corresponding to the first driving circuit Tx1.

In a specific time T2, the second driving circuit Tx2 is driven and the switch SW2 is turned on so as to receive sensing signals of the M sensing touch electrodes corresponding to the second driving circuit Tx2.

The driving and sensing of the driving circuits Tx will not be completed until an Nth driving circuit Txn is completely driven and sensed with the above-mentioned method.

During one of the specific times, one of the switches SW is correspondingly selected to be turned on, and the other switches SW are in a turned-off state for avoiding noise interference caused by other sensing circuits.

Consequently, the present disclosure which especially provides a single-layer multi-touch layer brings beneficial effects of lessening the thickness of the OLED device, simplifying the manufacturing process, and reducing the risk of damage to the display layer.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A touch display panel comprising a touch layer, the touch layer comprising:
N driving circuits, each of the N driving circuits connected with two or more driving touch electrodes; the N being an integer greater than or equal to one;
M receiving circuits, the M being an integer greater than or equal to one;
M×N sensing touch electrodes, each of the sensing touch electrodes being independent from the adjacent sensing touch electrodes;
N switches, each of the N switches comprising a controlling terminal, M input terminals connected to the M×N sensing touch electrodes correspondingly, and M output terminals connected to the M receiving circuits correspondingly;
wherein each of the driving circuits is correspondingly provided with the M sensing touch electrodes arranged in columns connected to the same switch.

2. The touch display panel of claim 1, wherein the N driving circuits are arranged in columns; the M input terminals of each of the switches is connected to the M sensing touch electrodes corresponding to the driving circuits in each column; the M output terminals of each of the switches is connected to the M receiving circuits.

3. The touch display panel of claim 1, wherein the driving touch electrodes and the sensing touch electrodes are independent of each other.

4. The touch display panel of claim 1, wherein the touch layer further comprises a bridging line; the bridging line is connected to the two adjacent driving touch electrodes on each of the driving circuits.

5. The touch display panel of claim 4, wherein each of the sensing touch electrodes comprises two or more metallic electrodes; the adjacent metallic electrodes are connected through the bridging line.

6. A method of driving a touch display panel, comprising:
driving an Nth driving circuit during a predetermined time period, the N being an integer greater than or equal to one;
turning an Nth switch on;
receiving a sensing signal of M sensing touch electrodes corresponding to the Nth driving circuit; the M being an integer greater than or equal to one.

7. The method of claim 6, wherein the touch display panel comprises:
N driving circuits, each of the N driving circuits connected with two or more driving touch electrodes;
M receiving circuits;
M×N sensing touch electrodes;
N switches, each of the N switches comprising a controlling terminal, M input terminals connected to the M×N sensing touch electrodes correspondingly, and M output terminals connected to the M receiving circuits correspondingly;
wherein each of the driving circuits is correspondingly provided with the M sensing touch electrodes arranged in columns connected to the same switch.

8. The method of claim 7, wherein the N driving circuits are arranged in columns; the M input terminals of each of the switches is connected to the M sensing touch electrodes corresponding to the driving circuits in each column; the M output terminals of each of the switches is connected to the M receiving circuits.

9. The method of claim 8, wherein selectively turning on one of the N switches during the predetermined time period.

10. A touch display panel comprising a touch layer, the touch layer comprising:
N driving circuits, each of the N driving circuits connected with two or more driving touch electrodes; the N being an integer greater than or equal to one;
M receiving circuits, the M being an integer greater than or equal to one;
M×N sensing touch electrodes;
N switches, each of the N switches comprising a controlling terminal, M input terminals connected to the M×N sensing touch electrodes correspondingly, and M output terminals connected to the M receiving circuits correspondingly;
wherein each of the driving circuits is correspondingly provided with the M sensing touch electrodes arranged in columns connected to the same switch.

11. The touch display panel of claim 10, wherein the N driving circuits are arranged in columns; the M input terminals of each of the switches is connected to the M sensing touch electrodes corresponding to the driving circuits in each column; the M output terminals of each of the switches is connected to the M receiving circuits.

12. The touch display panel of claim 10, wherein the driving touch electrodes and the sensing touch electrodes are independent of each other.

13. The touch display panel of claim 10, wherein the touch layer further comprises a bridging line; the bridging line is connected to the two adjacent driving touch electrodes on each of the driving circuits.

14. The touch display panel of claim 13, wherein each of the sensing touch electrodes comprises two or more metallic electrodes; the adjacent metallic electrodes are connected through the bridging line.
